(19) United States
(12) Patent Application Publication
(10) Pub. No.: US 2023/0187435 A1
(43) Pub. Date: Jun. 15, 2023

(54) DIODE CONFIGURATION FOR CIRCUIT PROTECTION

(71) Applicant: SKYWORKS SOLUTIONS, INC., Irvine, CA (US)

(72) Inventors: Min-Zing Tseng, Irvine, CA (US); Renfeng Jin, Irvine, CA (US)

(21) Appl. No.: 17/988,038

(22) Filed: Nov. 16, 2022

Related U.S. Application Data
(60) Provisional application No. 63/289,518, filed on Dec. 14, 2021.

(51) Int. Cl. H01L 27/02; H02H 9/02; H01L 29/93

(52) U.S. Cl. CPC H01L 27/0255; H01L 29/93; H02H 9/02

(57) ABSTRACT

A semiconductor device and a corresponding circuit for shunting current in a circuit protection configuration is disclosed. An example device includes a first semiconductor region having an anode electrical contact, a second semiconductor region having a cathode electrical contact, a third semiconductor region extending between the first semiconductor region and the second semiconductor region, the second semiconductor region and the third semiconductor region forming a PN junction therebetween, and a gate coupled to the third semiconductor region. The gate is controllable between a first mode in which additional space charges are induced in the semiconductor region to deplete the semiconductor region, and a second mode in which additional space charges are not induced in the semiconductor region.

### CROSS-REFERENCE TO RELATED APPLICATIONS

This application claims priority under 35 U.S.C. § 119(e) to U.S. Provisional Application Serial No. 63/289,518 titled “DIODE CONFIGURATION FOR CIRCUIT PROTECTION,” filed on Dec. 14, 2021, which is hereby incorporated by reference in its entirety.

### FIELD

Embodiments of the present disclosure relate to the field of electronic circuit protection, and more particularly to diode arrangements for circuit protection.

### DESCRIPTION OF THE RELATED TECHNOLOGY

Computer devices, for example mobile devices may be highly likely to be subjected to both component-level human body model (HBM) and system-level electrostatic discharge (ESD) and/or electrical overstress (EOS) surge events and corresponding requirements for power handling in response to overvoltage stress. Some methods of protecting circuits from high supply voltages involve restricting the allowed supply voltage and/or adding one or more diodes between the supply voltage and a clamp field-effect transistor (FET). Some methods involve adding one or more diodes in a current shunting arrangement to direct current to ground, or to short across the terminals of the overvoltage source, and away from the circuit to be protected. In some examples, during an overvoltage stress event, the computer device may be excited with a high instantaneous voltage, for example a short duration 1,000 V pulse, which may lead to circuit damage if the circuit is not protected appropriately.

### SUMMARY

According to one embodiment there is provided a semiconductor device for shunting current in a circuit protection configuration, the device comprising a first semiconductor region having an anode electrical contact, a second semiconductor region having a cathode electrical contact, a third semiconductor region, and a gate. The third semiconductor region extends between the first semiconductor region and the second semiconductor region, the second semiconductor region and the third semiconductor region forming a PN junction therebetween. The gate is coupled to the third semiconductor region, and the gate is controllable between a first mode in which additional space charges are induced in the semiconductor region to deplete the semiconductor region, and a second mode in which additional space charges are not induced in the semiconductor region.

In one example, the gate is a gate electrode adjacent to the third semiconductor region and the gate electrode is configured in the first mode to generate an electric field to exert a potential change in the third semiconductor region.

In one example, the gate electrode forms a p-varactor with the adjacent third semiconductor region. In one example, the gate electrode is formed from a heavily doped polysilicon layer adjacent to an oxide insulator layer.

In one example, the gate is a fourth semiconductor region embedded in the third semiconductor region and configured to form a PN junction between the third and fourth semiconductor regions, the fourth semiconductor region configured to induce additional space charges in the third semiconductor region when a bias voltage is applied to the fourth semiconductor region.

In one example, a depth of the third semiconductor region is larger than a depth of the fourth semiconductor region.

In one example, the fourth semiconductor region is a heavily doped N+ region and the third semiconductor region is a p-type semiconductor region.

In one example, the first semiconductor region is a P+ region, the second semiconductor region is an N+ region, and the third semiconductor region is a p-type semiconductor region.

In one example, the semiconductor device further comprises a central P+ semiconductor region that divides the third semiconductor region into two semiconductor regions.

In one example, the semiconductor device is fabricated as a silicon-on-insulator device.

In one example, PN junction is configured to be forward biased.

In one example, the second mode is a surge event mode during which the voltage received at the anode electrical contact is greater than a threshold voltage, and the first mode is a normal operation mode during which the voltage received at the anode electrical contact is less than the threshold voltage.

According to another embodiment, there is provided a circuit for shunting current in a circuit protection configuration, the circuit comprising a semiconductor device according to the above embodiment, the anode electrical contact for coupling to a first voltage source and the cathode electrical contact for coupling to ground, and a coupling circuit configured to couple a second voltage level to the gate when a voltage of the first voltage source is below a threshold voltage, and configured to pull the gate down to a ground voltage when the voltage of the first voltage source is above the threshold voltage.

In one example, the coupling circuit comprises an n-channel field-effect transistor (FET) having a gate and a selectively conductive channel, a first p-channel FET having a gate coupled to the anode electrical contact of the semiconductor device and having a selectively conductive channel configured to selectively couple the second voltage level to the gate of the semiconductor device, and a second p-channel FET having a gate configured to couple to the second voltage level and having a selectively conductive channel configured to selectively couple the anode electrical contact to the gate of the n-channel FET, the selectively conductive channel of the n-channel FET being configured to selectively couple the gate of the semiconductor device to a ground node.

In one example, the circuit further comprises a resistor placed in the path between the gate of the semiconductor device and the selectively conductive channel of the n-channel FET.

In one example, the cathode electrical contact of the semiconductor device is coupled to a ground node.

In one example, the anode electrical contact of the semiconductor device is coupled to the first voltage source in parallel with a circuit block to be protected, the circuit configured to shunt excess voltage from the first voltage source.

In one example, the coupling circuit comprises a voltage peak detector coupled to the first voltage source and configured to sense a maximum voltage of the first voltage source, a comparator coupled to the voltage peak detector and the threshold voltage, the comparator configured to output an indication of whether the maximum voltage of the first voltage source is greater than the threshold voltage, and a gate driver configured to receive the indication from the comparator and configured to control the voltage coupled to the gate based on the indication.

In one example, the second voltage level coupled to the gate by the gate driver when the first voltage source is below a threshold voltage is a variable voltage level.

In one example, the gate driver is configured to pull the gate down to a ground voltage in the event that a portion of the coupling circuit becomes unpowered.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a schematic illustration of a PN semiconductor diode;

FIG. 2 is a schematic illustration of a stacked PN semiconductor diode;

FIG. 3 is a schematic circuit diagram of a current shunting circuit protection arrangement using a stacked PN semiconductor diode;

FIG. 4 is a graph illustrating the forward current-voltage characteristics of a one stack silicon diode and a two stack silicon diode;

FIG. 5 is a schematic circuit diagram of a current shunting circuit protection arrangement using a diode according to aspects of the present invention;

FIG. 6A is a schematic illustration of a modified semiconductor diode in a surge event mode according to aspects of the present disclosure;

FIG. 6B is a schematic illustration of a modified semiconductor diode in a normal operation mode according to aspects of the present disclosure;

FIG. 7 is a diode control circuit for a current shunting circuit protection arrangement according to aspects of the present disclosure;

FIG. 8A is a schematic illustration of a modified semiconductor diode in a surge event mode according to further aspects of the present disclosure;

FIG. 8B is a schematic illustration of a modified semiconductor diode in a normal operation mode according to further aspects of the present disclosure;

FIG. 9 is a diode control circuit for a current shunting circuit protection arrangement according to further aspects of the present disclosure;

FIG. 10 is an active diode control circuit for a current shunting circuit protection arrangement according to aspects of the present disclosure;

FIG. 11 is a die implemented in a packaged module having one or more features according to aspects of the present disclosure; and

FIG. 12 depicts an example wireless device having one or more features according to aspects of the present disclosure.

### DETAILED DESCRIPTION

Aspects and embodiments described herein are directed to an improved diode arrangement for circuit protection having a low forward resistance and a controllable turn-on voltage. This can provide a simple and efficient current shunting arrangement for power surge or electrostatic discharge situations / events.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

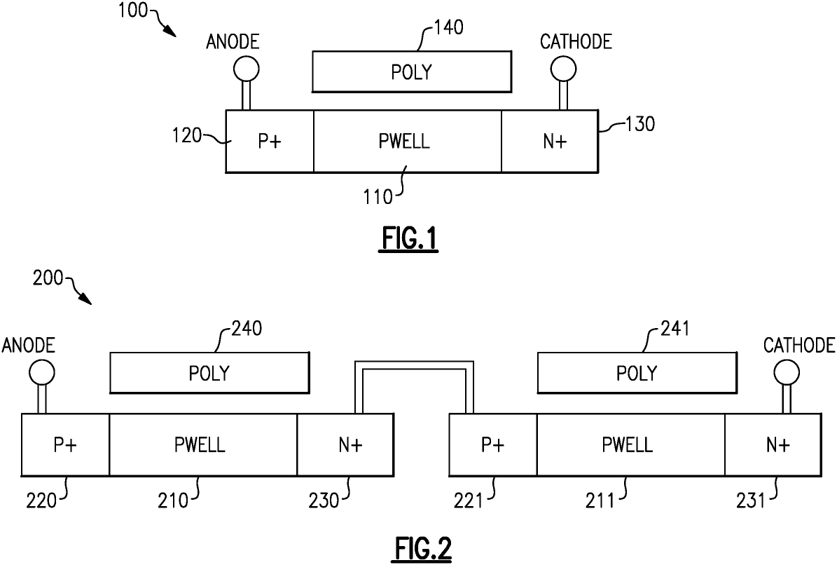

Single diodes are simple and efficient current shunting devices that can be used in arrangements for providing circuit protection to a circuit block to be protected. An example of a PN semiconductor diode 100 implemented with a silicon-on-insulator (SOI) structure is illustrated in FIG. 1. The diode 100 comprises a p-type semiconductor substrate or P-Well 110 having a positively doped P+ region 120 at one end, a negatively doped N+ region 130 at the other end, and a polysilicon stripe 140 that may act as a gate electrode. The P+ region 120 may include an anode electrical contact, and the N+ region 130 may include a cathode electrical contact. The SOI diode may be built in silicon that sits on an insulator, such as an insulating buried oxide (BOX). The BOX typically sits on a handle wafer, which may also be silicon, but this handle wafer may instead be glass, borosilicon glass, fused quartz, sapphire, silicon carbide, or any other electrically-insulating material. In FIG. 1, the gate electrode 140 is indicated as comprising polysilicon; however, it will be appreciated that alternative silicide materials or metal composites may be used instead in other examples.

The P+ region 120 and the N+ region 130 form a PN junction having a given junction voltage across the depletion region formed at the PN junction. When a positive voltage is applied to the P side 120 of the diode, via the anode, the junction’s depletion region will be narrowed. If the positive voltage is larger than the given junction voltage, then the diode will become forward biased and the junction will become conductive, thus allowing electrons to flow easily from the P-type to the N-type (i.e., a current to flow from the anode to the cathode). As such, this junction voltage may also be referred to as the diode’s turn-on voltage. If the applied positive voltage is less than the junction voltage, then the diode junction will behave as an insulator, thus resisting the flow of current from the anode to the cathode.

The value of the diode’s junction voltage, and therefore turn-on voltage, is a material property and as such is predominantly defined by the choice of semiconductor material. For example, a silicon diode will typically have a junction / turn-on voltage of around 0.7 V, while a germanium diode will typically have a junction / turn-on voltage of around 0.3 V. While it may be possible to vary this turn-on voltage slightly during the manufacturing process of the diode, the possible range of turn-on voltages is very small and accordingly alternative methods are needed to adapt the turn-on voltage to suit a given voltage requirement in a circuit protection implementation.

If the operational voltage of the circuit is expected to exceed this turn-on voltage, then the diode 100 would spend at least a portion of its normal operational life (i.e., outside of an ESD or EOS surge event) in the ON state, which would therefore provide a route for a high leakage current and disrupt the normal operation of the circuit to be protected. Accordingly, there is a need to provide diode arrangements having a higher turn-on voltage in order to perform effective circuit protection based on the expected supply level and leakage considerations of the circuit block to be protected. Such a diode arrangement can be achieved by connecting a plurality of diodes in series. This arrangement may be referred to as a stacked diode, or a diode string, and the net turn-on voltage of the stacked diode will be approximately equal to the sum of the turn-on voltages of the individual diodes forming the stacked diode.

In one example, the plurality of diodes connected in series may be monolithically integrated in a single piece of semiconductor substrate by utilizing dielectrically-isolated trenching and silicon-on-insulator (SOI) substrates, which enable formation of “silicon islands” to insulate a diode structure electrically from adjacent structures. The plurality of diodes connected in series may comprise a scalable number of monolithically-integrated forward-bias PN diodes, wherein the summation of the forward-bias voltage of each PN diode is equivalent to a net clamping voltage value for an electrical circuit protection design.

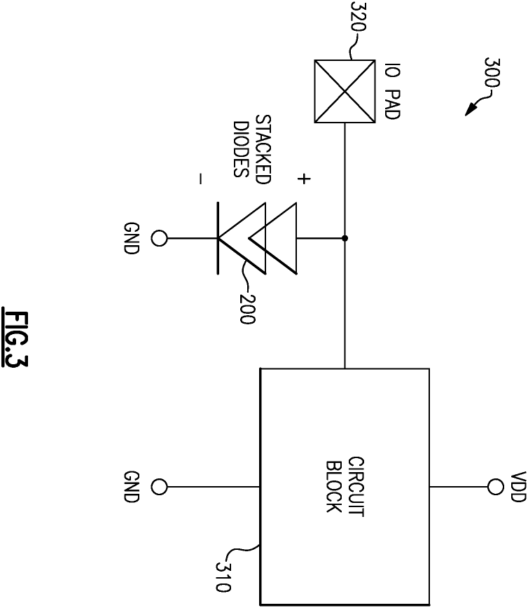

FIG. 2 is a schematic illustration of a stacked PN semiconductor diode 200 implemented with a SOI structure. The stacked diode 200 may be formed from two diodes 100 arranged in series with the cathode of a first diode electrically connected to the anode of a second diode. This arrangement may be referred to as a two stack diode. As illustrated, the first diode comprises a p-type semiconductor substrate or P-Well 210 having a positively doped P+ region 220 at one end, a negatively doped N+ region 230 at the other end, and a gate electrode 240. The P+ region 220 and the N+ region 230 form a first PN junction having a given first junction voltage across the depletion region formed at the first PN junction.

Similarly, the second diode comprises a p-type semiconductor substrate or P-Well 211 having a positively doped P+ region 221 at one end, a negatively doped N+ region 231 at the other end, and a gate electrode 241. The N+ region 230 of the first diode is electrically connected to the P+ region 221 of the second diode. The P+ region 221 and the N+ region 231 form a second PN junction having a given second junction voltage across the depletion region formed at the second PN junction. The P+ region 220 may include an anode electrical contact, and the N+ region 231 may include a cathode electrical contact. While the diode stack 200 is shown comprising two diodes, it will be appreciated that this may be scaled to include more than two diodes. In some cases, a single diode may be referred to as a one stack diode.

The turn-on voltage for the two stack diode 200 may be approximately equal to the sum of the first junction voltage and the second junction voltage. This higher turn-on voltage may then provide adequate headroom for the voltage supply of certain circuits to be protected, and therefore control any leakage current to be within acceptable parameters. Alternatively, the higher turn-on voltage may enable the leakage current to be maintained in respect of a circuit having a higher voltage supply. It will be appreciated that the turn-on voltage may not be a simple multiple in practice, for example due to parasitic effects in non-ideal diodes.

FIG. 3 is a schematic circuit diagram of a current shunting circuit protection arrangement 300 using a stacked PN semiconductor diode 200. The current shunting circuit protection arrangement 300 comprises a stacked diode 200, a circuit block 310, and an IO pad 320. The circuit block 310 may be the circuit block to be protected from the ESD or EOS surge event and may be configured to operate at a voltage level VDD. The circuit block 310 is electrically coupled to the IO pad 320, which may correspond to a low voltage metal pad, or other port, that facilitates electrical input / output between the circuit block 310 and the device in which the circuit block is implemented and/or user input devices.

As can be seen from FIG. 3, the anode of the stacked diode 200 is connected to the path between the IO pad 320 and the circuit block 310 to be protected in a parallel arrangement, with the cathode of the stacked diode 200 connecting the IO pad 320 to a short to a ground level GND. By matching the turn-on voltage of the stacked diode 200 to the requirements (including any overhead) of the supply voltage VDD, the voltage between the circuit block 310 and the IO pad 320, which is also applied to the anode of the stacked diode 200, may be expected to be smaller than the turn-on voltage of the stacked diode such that the stacked diode remains in the OFF state during normal operations in order to prevent the leakage of current from the IO pad 320 or the circuit block 310 to the ground short.

If the IO pad 320 experiences an ESD or EOS surge event, the voltage between the IO pad and both the stacked diode 200 and the circuit block 310 will exceed the expected operational voltage. When this voltage exceeds the turn-on voltage of the stacked diode 200, the stacked diode will become forward biased and conducting (i.e., in the ON state), and therefore the IO pad 320 will be shorted to ground. By providing a low impedance path to ground, the stacked diode may shunt the surge current to the ground and away from the circuit block 310 to be protected.

In order for this to be effective, the arrangement should be configured such that the circuit block itself has a larger resistance than the short to ground through the stacked diode 200. However, the series resistance of the two stack diode 200 in the forward biased mode (i.e., once the applied voltage is larger than the turn-on voltage) will be larger than the resistance of a one stack diode 100, which will reduce the relative difference in the resistance provided by the circuit block 310 and the short to ground via the stacked diode 200, which in turn will reduce the current shunting capability of the two stack diode 200 with respect to the one stack diode 100. This increases the risk of current leaking into the circuit block during a surge event even if the stacked diode is in an ON / conducting state. Furthermore, this increased resistance may increase the temperature of the diode stack during operation, which may in turn lead to overheating and device failure in certain conditions.

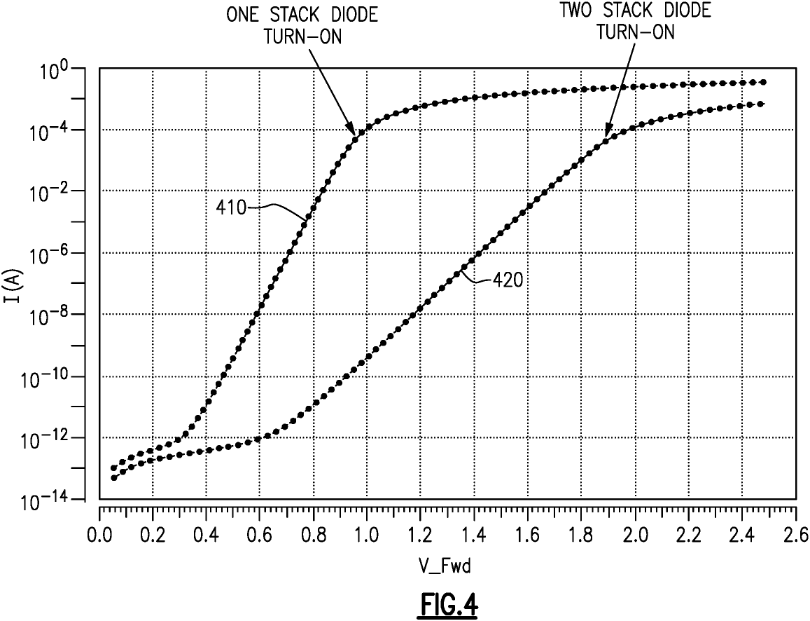

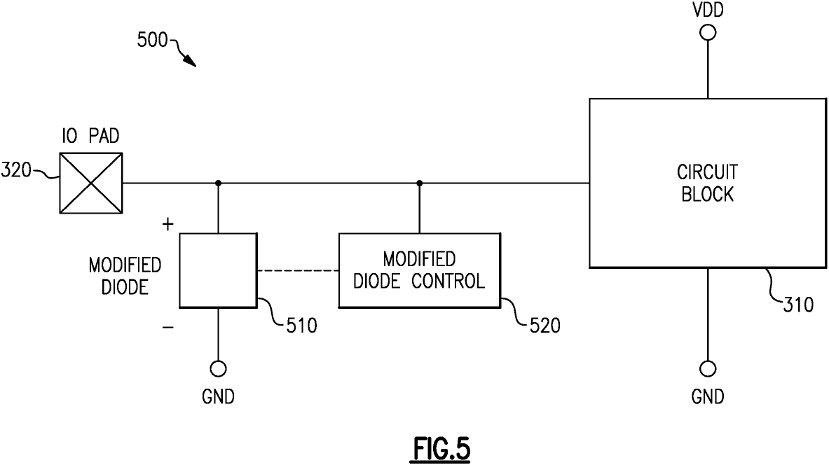

FIG. 4 is a graph illustrating the forward current-voltage characteristics of a one stack silicon diode and a two stack silicon diode. Plot 410 shows the forward current-voltage characteristics of the one stack silicon diode, with the approximate turn-on voltage of the one stack diode indicated by the labelled arrow. Plot 420 shows the forward current-voltage characteristics of the two stack silicon diode, with the approximate turn-on voltage of the two stack diode indicated by the labelled arrow. As can be seen from the graph, the forward biased turn-on voltage of the two stack diode is approximately twice that of the one stack diode. However, the impact of the comparatively high series resistance of the two stack diode can also be seen, i.e., for a given forward voltage, the current flow through the two stack diode is substantially less than the current flow through the one stack diode. This can create a design tension between the total diode resistance and the amount of leakage current when determining the turn-on voltage to be used in a given situation.

FIG. 5 is a schematic circuit diagram of a current shunting circuit protection arrangement 500 using a diode according to aspects of the present disclosure. The current shunting circuit protection arrangement 500 comprises a modified diode 510, a diode control block 520, a circuit block 310, and an IO pad 320. As in FIG. 3, the circuit block 310 may be the circuit block to be protected from the ESD or EOS surge event and may be configured to operate at a voltage level VDD. The circuit block 310 is electrically coupled to the IO pad 320, which may correspond to a low voltage metal pad, or other port, that facilitates electrical input / output between the circuit block 310 and the device in which the circuit block is implemented.

The anode of the modified diode 510 is connected to the path between the IO pad 320 and the circuit block 310 to be protected in a parallel arrangement, with the cathode of the modified diode 510 connecting the IO pad 320 to a short to a ground level GND. The modified diode may be configured to operate in two modes, for example a surge event mode and a normal operation mode. The transition between these two modes / operational states may be controlled by a diode control block 520 that is coupled to the path between the IO pad 320 and the circuit block 310. In this manner, the diode control block 520 may sense the voltage in the path between the IO pad 320 and the circuit block 310 and, in response, affect (represented by the dashed line) the current-voltage characteristic of the modified diode 510.

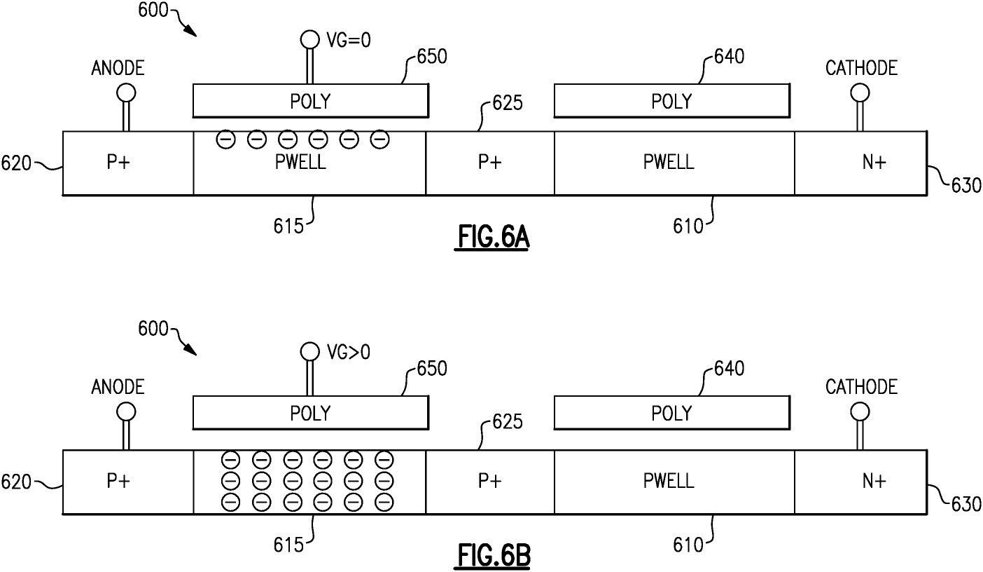

An example modified diode 510 may be the modified diode 600 schematically illustrated in FIG. 6A, which is represented in a surge event mode according to aspects of the present invention. In a similar manner to the single / one stack diode 100 of FIG. 1, the diode 600 comprises a positively doped P+ region 620 at one end, a negatively doped N+ region 630 at the other end, a p-type semiconductor substrate or P-Well 610 positioned between the P+ and N+ regions, and a gate electrode 640. However, the diode 600 further comprises an additional p-type semiconductor substrate or P-Well 615 positioned between the P+ and N+ regions, as well as a further positively doped P+ region 625 positioned between P-Wells 610 and 615.

In this arrangement the current may be configured to be received at an anode in the P+ region 620, and then flow from P+ region 620 to P-Well 615, then to the P+ region 625, then to the P-Well 610, and then to the N+ region 630, which includes the cathode electrical contact. The P+ region 625 and the N+ region 630 form a PN junction having a given junction voltage across the depletion region formed at the PN junction. When a positive voltage is applied to the P+ region 620 of the diode, via the anode, the junction’s depletion region will be narrowed. If the positive voltage is larger than the given junction voltage, then the diode will become forward biased and the junction will become conductive, thus allowing electrons to flow easily from the P-type region to the N-type region and, in general, a current to flow from the anode to the cathode. Because a single PN junction is included in the modified diode, it can be expected to have a turn-on voltage and total diode resistance that is similar to that of the single diode 100. For example, the turn-on voltage may be around 0.7 V if the diode 600 is made from silicon. The total diode resistance of the diode 600 may be slightly larger than that of the diode 100 due to the extended conduction path provided by the additional P-Well region 615; however, this would be expected to be significantly smaller than that of the two stack diode such as diode 200.

In this manner, the diode 600 may have similar forward current-voltage characteristic to a one stack diode in this surge event mode such that the surge current can be conducted through the diode 600 with a low forward resistance and a high current shunting capability. In the current shunting circuit protection arrangement 500, this surge current may then be shunted to the GND in order to protect the circuit block 310 from this surge current.

A gate electrode 650 is also illustrated in FIG. 6A. This gate electrode 650 forms part of the diode control block 520 and may be configured to control the state of the modified diode 600 between the surge event and normal operation modes. In the surge event mode illustrated in FIG. 6A, the voltage at this gate electrode 650 is pulled down to ground, which is represented in FIG. 6A by gate voltage VG = 0. In the absence of a gate voltage, the P-Well 615 may be in a partially depleted state with a relatively small number of fixed space charges, which are illustrated in the P-Well 615 by a minus symbol in a circle.

FIG. 6B is a schematic illustration of a modified semiconductor diode in a normal operation mode according to aspects of the present invention. In the normal operation mode, a positive gate voltage is applied to the gate electrode 650. The positive bias at the gate electrode 650 may create an electric field that induces a drift velocity moving mobile charge carriers away from the side of the P-Well 615 closest to the gate electrode 650. This increases the number of fixed space charges in the P-Well 615, with the polarity and amount of fixed space charges being controlled by the diode control block 520 causing the gate electrode 650 to exert different voltage levels and polarities onto the semiconductor region 615 in front of the PN junction of the diode 600.

At an appropriate gate bias voltage, this causes the P-Well 615 to become fully depleted with many fixed space charges being induced in the P-Well 615. This large number of fixed space charges creates a space charge effect whereby the cloud of negative fixed space charges act as a Coulomb barrier to repel electrons emitted from the anode, which increases the resistance of the conductive path leading to the PN junction of the diode, and thus increases the effective turn-on voltage of the modified diode 600 as a whole during the normal operation mode.

In this manner, the modified diode 600 may be selected such that the effective turn-on voltage of the diode 600 (when the P-Well 615 is fully depleted by an appropriate gate bias voltage) is matched to the requirements (including any overhead) of the supply voltage VDD. This means that, during normal operations, the voltage between the circuit block 310 and the IO pad 320, which is also applied in parallel to the anode of the modified diode 600, would be expected to be smaller than the effective turn-on voltage of the diode 600 such that the diode remains in the non-conducting / OFF state and the leakage of current from the IO pad 320 or the circuit block 310 to the ground short is prevented.

The diode control block is preferably configured to pull this gate bias voltage down to ground if the IO pad 320 experiences an ESD or EOS surge event (i.e., the voltage between the IO pad and both the stacked diode 200 and the circuit block 310 exceeds the expected operational voltage), which will prevent space charges from being induced in the P-Well 615 and revert the diode 600 to a partially depleted state. This reduces the resistance of the conductive path through the P-Well 615 and in turn reduces the effective turn-on voltage of the diode 600 back to that approximating a one stack diode, which will be referred to as the base turn-on voltage of the modified diode. Since the diode 600 is experiencing an ESD or EOS surge event, the voltage applied will be larger than the reduced / base turn-on voltage and the diode 600 will be in the conducting / ON state. The current-voltage characteristic of the diode 600 in the surge event mode approximates that of a one stack diode 100, which means that the surge current from the IO pad 320 may be efficiently shunted to ground with a similarly low forward resistance in order to protect the circuit block 310. In addition to the improved current-voltage characteristics of the modified diode 600, this arrangement may reduce the temperature of the shunting diode during surge event operation, which in turn may reduce the likelihood of the diode 600 overheating and leading to device failure in certain conditions.

FIG. 6A and FIG. 6B indicate that the gate electrode is formed from polycrystalline silicon. In one example, this may be a heavily doped polysilicon stripe on top of an oxide insulator to exert a potential change on the P-type semiconductor region / P-Well 615 underneath. However, it will be appreciated that the present disclosure is not limited to this example, and that alternative silicide materials or metal composites may be used instead in other examples. In a generalized version of this example, a p-varactor is added in front of the P-Well to N+ diode whereby a positive bias voltage applied to a polysilicon gate of the varactor may deplete the P-Well underneath in order to induce negative space charges and create a high resistance path in front of the diode.

While the example semiconductor diode illustrated in FIG. 6A and FIG. 6B includes a central P+ region 625, it will be appreciated that this P+ region is optional and could be omitted in some examples such that a single extended P-Well was present between the P+ region 620 and the N+ region 630.

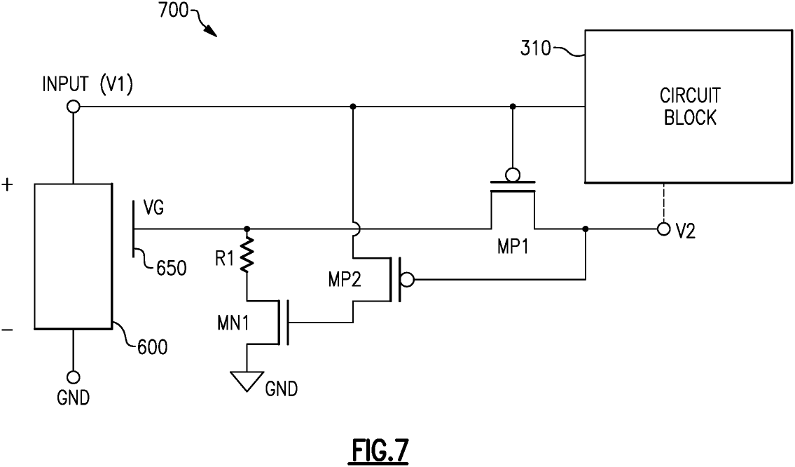

In general, the diode control block 520 may be configured to apply a desired bias voltage to the gate electrode 650, in order to fully deplete the P-Well 615 and induce fixed space charges, during normal operation, and to pull this bias voltage down to ground in response to sensing a ESD or EOS surge event. One example of such a diode control circuit is illustrated in FIG. 7. The source of the potential surge, illustrated as an IO pad 320 in FIG. 5, is represented as the input, which has a voltage V1 and is connected to the circuit block 310 as well as the anode of the modified diode 600. A voltage V2 is supplied to the diode control circuit as a reference voltage level, which may optionally be supplied by the circuit block 310 as illustrated by the dotted line in FIG. 7.

The diode control circuit of FIG. 7 comprises a p-channel field-effect transistor (FET) MP1, a p-channel FET MP2, an n-channel FET MN1, and a resistor R1. In a normal operation mode, reference voltage V2 will be configured to be higher than the input voltage V1. In this case where V2 is higher than the sum of V1 and the threshold voltage of MP1, then the MP1 p-channel FET will turn ON and the V2 voltage will be applied to the gate electrode 650, accordingly the gate voltage will be VG = V2. In this configuration, MP2 will be OFF since the gate of MP2 is held high by V2. This in turn means that the gate of MN1 will be held low (since MP2 is non-conducting in this situation) and MN1 will also be OFF. Resistor R1 helps to suppress any leakage current from V2 during normal operations such that VG = V2. The voltage V2 will be configured to fully deplete the P-Well 615 and induce fixed space charges such that the diode 600 is in the normal operation mode described above with reference to FIG. 6B.

In a surge event, V1 will increase such that it is higher than the sum of V2 and the threshold voltage of MP2. In this case, the gate of MP1 will be held high by V1 > V2 and MP1 will be OFF, thus closing the conductive path from V2 to the gate electrode 650. Conversely, the gate of MP2 will be held low such that MP2 is ON and conducts the high V1 to the gate of MN1. This then turns MN1 ON such that VG is pulled to ground GND via the resistor R1, i.e.,, VG = 0. In this situation, the gate electrode will no longer fully deplete the P-Well 615 such that the diode 600 is in the surge event mode described above with reference to FIG. 6A.

It will be appreciated that the present invention is not limited to this configuration of FETs and that alternative circuit configurations could be used to supply a given voltage to the gate electrode 650 in the normal operation mode, and to pull the gate electrode 650 voltage supply down to ground in the surge event mode.

The above described example controls the mode of the diode 600 by inducing additional space charges in the P-Well 615 due to the electric field of the gate electrode 650. This is particularly applicable to diode structures having a relatively thin depth / material thickness - the thicker the material is, the higher the gate voltage will need to be in order to fully deplete the P-Well 615 and to achieve the normal operation mode, which may be difficult for particularly thick materials and may result in undesirable leakage current in this mode.

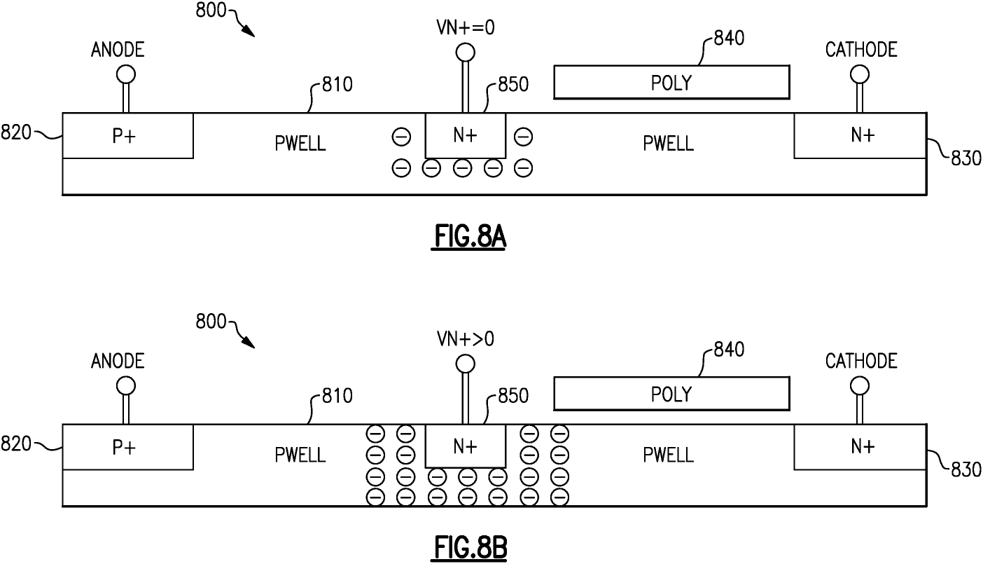

In a further example, the modified diode 510 may be the modified diode 800 schematically illustrated in FIG. 8A, which is represented in a surge event mode according to aspects of the present invention. In a similar manner to the single / one stack diode 100 of FIG. 1 and the modified diode 600 of FIG. 6A and FIG. 6B, the diode 800 comprises a positively doped P+ region 820 at one end, a negatively doped N+ region 830 at the other end, a p-type semiconductor substrate or P-Well 810 positioned between the P+ and N+ regions, and a gate electrode 840. However, the diode 800 further comprises an additional N+ region 850 embedded in the p-type semiconductor substrate or P-Well 810. It will be appreciated that the thickness / depth of the embedded N+ region 850 is smaller than the thickness / depth of the P-Well 810 such that a conductive path through the P-Well still exists underneath the N+ region 850.

In this arrangement, the current may be configured to be received at an anode in the P+ region 820, then flow from P+ region 820 to P-Well 810, and then to the N+ region 830, which includes the cathode electrical contact. The P+ region 820 and the N+ region 830 form a PN junction having a given junction voltage across the depletion region formed at the PN junction.

When a positive voltage is applied to the P+ region 820 of the diode, via the anode, the junction’s depletion region will be narrowed. If the positive voltage is larger than the given junction voltage, then the diode will become forward biased and the junction will become conductive, thus allowing electrons to flow easily from the P-type region to the N-type region and, in general, a current to flow from the anode to the cathode. Because a single PN junction is included in the modified diode, it can be expected to have a turn-on voltage and total diode resistance that is similar to that of the single diode 100. For example, the turn-on voltage may be around 0.7 V if the diode 800 is made from silicon. The total diode resistance of the diode 800 may be slightly larger than that of the diode 100 due to the extended conduction path provided through the extended P-Well region 810 and around the N+ region 850; however, this would be expected to be significantly smaller than that of the two stack diode such as diode 200.

In this manner, the diode 800 may have similar forward current-voltage characteristic to a one stack diode in this surge event mode such that the surge current can be conducted through the diode 800 with a low forward resistance and a high current shunting capability. In the current shunting circuit protection arrangement 500, this surge current may then be shunted to the GND in order to protect the circuit block 310 from this surge current.

A bias voltage electrical contact for applying a bias voltage VN+ to the additional N+ region 850 is also illustrated in FIG. 8A. This bias voltage electrical contact forms part of the diode control circuit of the diode control block 520 and may be configured to control the state of the modified diode 800 between the surge event and normal operation modes. In the surge event mode illustrated in FIG. 8A, the voltage applied to the additional N+region 850 by this bias voltage electrical contact is pulled down to ground, which is represented in FIG. 8A by bias voltage VN+ = 0. Fixed space charges are illustrated in the P-Well 810 by a minus symbol in a circle. In the absence of a gate voltage, the P-Well 810 may be in a partially depleted state with a relatively small number of fixed space charges.

FIG. 8B is a schematic illustration of a modified semiconductor diode in a normal operation mode according to further aspects of the present invention. In the normal operation mode, a positive bias voltage is applied to the additional embedded N+ region 850 in order to fully deplete the adjacent area of the P-Well 810 and induce additional negative space charges in the semiconductor region in front of / before the diode (with respect to the flow of electrons through the conductive path from the anode to the cathode). At an appropriate bias voltage, the large number of fixed negative space charges creates a space charge effect whereby the cloud of negative fixed space charges act as a Coulomb barrier to repel electrons emitted from the anode, which increases the resistance of the conductive path leading to the PN junction of the diode and thus increases the effective turn-on voltage of the modified diode 800 as a whole during the normal operation mode.

In this manner, the modified diode 800 may be selected such that the effective turn-on voltage of the diode 800 (when the P-Well 810 is fully depleted by an appropriate bias voltage) is matched to the requirements (including any overhead) of the supply voltage VDD. This means that, during normal operations, the voltage between the circuit block 310 and the IO pad 320, which is also applied to the anode of the modified diode 800, would be expected to be smaller than the effective turn-on voltage of the diode 800 such that the diode remains in the non-conducting / OFF state and the leakage of current from the IO pad 320 or the circuit block 310 to the ground short is prevented.

The diode control block is preferably configured to pull this bias voltage down to ground if the IO pad 320 experiences an ESD or EOS surge event (i.e., the voltage between the IO pad and both the stacked diode 200 and the circuit block 310 exceeds the expected operational voltage), which will prevent space charges from being induced in the P-Well 810 and revert the diode 600 to a partially depleted state. This reduces the resistance of the conductive path through the P-Well 810 and in turn reduces the effective turn-on voltage of the diode 800 back to that approximating a one stack diode. While the diode 800 is experiencing an ESD or EOS surge event, the voltage applied will be larger than the reduced turn-on voltage and the diode 800 will be in the conducting / ON state. The current-voltage characteristic of the diode 800 in the surge event mode approximates that of a one stack diode 100, which means that the surge current from the IO pad 320 may be efficiently shunted to ground with a similarly low forward resistance in order to protect the circuit block 310. In addition to the improved current-voltage characteristics of the modified diode 800, this arrangement may reduce the temperature of the shunting diode during surge event operation, which in turn may reduce the likelihood of the diode 800 overheating and leading to device failure in certain conditions.

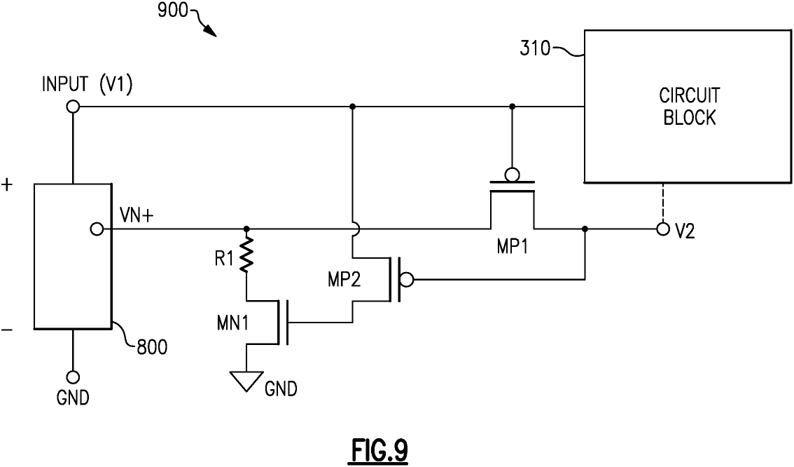

In general, the diode control block 520 may be configured to apply a desired bias voltage to the additional N+ region 850, in order to fully deplete the P-Well 810 and induce fixed space charges, during normal operation, and to pull this bias voltage down to ground (so that fixed space charges are not induced) in response to sensing a ESD or EOS surge event. One example of such a diode control circuit is illustrated in FIG. 9. The source of the potential surge, illustrated as an IO pad 320 in FIG. 5, is represented as the input, which has a voltage V1 and is connected to the circuit block 310 as well as the anode of the modified diode 800. A voltage V2 is supplied to the diode control circuit as a reference voltage level, which may optionally be supplied by the circuit block 310 as illustrated by the dotted line in FIG. 9.

The diode control circuit of FIG. 9 comprises a p-channel FET MP1, a p-channel FET MP2, an n-channel FET MN1, and a resistor R1. In a normal operation mode, reference voltage V2 will be configured to be higher than the input voltage V1. In this case where V2 is higher than V1 plus the threshold voltage of MP1, then the MP1 p-channel FET will turn ON and the V2 voltage will be applied to the bias voltage electrical contact and, in turn, the additional N+ region 850. Accordingly, the bias voltage will be VN+ = V2. In this configuration, MP2 will be OFF since the gate of MP2 is held high by V2, this in turn means that the gate of MN1 will be held low (since MP2 is non-conducting in this situation) and to MN1 will also be OFF. Resistor R1 helps to suppress any leakage current from V2 during normal operations such that VN+ = V2. The voltage V2 may be configured to fully deplete the P-Well 810 and induce fixed space charges such that the diode 800 is in the normal operation mode described above with reference to FIG. 8B.

In a surge event, V1 will increase such that it is higher than V2 plus the threshold voltage of MP2. In this case, the gate of MP1 will be held high by V1 > V2 and MP1 will be OFF, thus closing the conductive path from V2 to the bias voltage electrical contact of the N+ region 850. Conversely, the gate of MP2 will be held low such that MP2 is ON and conducts the high V1 to the gate of MN1. This then turns MN1 ON such that VN+ is pulled to ground GND via the resistor R1, i.e., VN+ = 0. In this situation, the additional N+ region 850 will no longer fully deplete the P-Well 810 such that the diode 800 is in the surge event mode described above with reference to FIG. 8A.

It will be appreciated that the present invention is not limited to this configuration of FETs and that alternative circuit configurations could be used to supply a given bias voltage VN+ to the embedded additional N+ region 850 in the normal operation mode, and to pull the bias voltage VN+ down to ground in the surge event mode.

The above described example controls the mode of the diode 800 by inducing additional space charges in the P-Well 810 due to the positive bias voltage applied to the additional embedded N+ region 850. This is particularly applicable to diode structures having a comparatively thick depth / material thickness with respect to the example of diode 600. For example, the P-Well 810 must be thicker / deeper than the thickness / depth of the embedded N+ region 850 in order to allow a conductive path in the P-Well 810 and around the N+ region 850 in the surge event mode.

It will be appreciated that the present disclosure is directed to semiconductor devices and corresponding circuits for shunting current comprising a diode PN junction and an extended semiconductor region (between the anode of the device and the PN junction) in which additional space charges can be induced in order to selectively increase the resistance of the conductive path through the semiconductor device. During normal operation (outside of a surge event) additional space charges are induced in the semiconductor device to increase the total diode resistance and turn-on voltage of the semiconductor device and to reduce any leakage current during normal operation. During a surge event (when the sensed voltage is larger than a threshold voltage) the diode control block ceases inducing additional space charges in the semiconductor device to reduce the total diode resistance of the semiconductor device for efficient current shunting.

One example described above utilizes a gate electrode to induce these additional space charges by generating an electric field that acts on a portion of the semiconductor conductive path in order to fully deplete it. Another example describes above utilizes an additional PN junction embedded in the semiconductor conductive path to induce these additional space charges by increasing a depletion region around the additional PN junction by applying a bias voltage to the additional PN junction. Further variations and equivalents of these examples for inducing additional space charges in such a semiconductor region will be apparent to the skilled person and fall within the scope of the present disclosure.

The example diode control circuits of FIG. 7 and FIG. 9 use a voltage level V2 for both the threshold voltage (for comparing to the input voltage V1 to determine whether the circuit is in a normal operation mode or a surge event mode) and the gate voltage VG / bias voltage VN+ (that is applied to the gate to selectively induce additional space charges in the modified diode); however, it will be appreciated that alternative circuits could use different voltage levels within the context of the present disclosure. E.g., V2 could be the voltage applied to the gate to selectively induce additional space charges in the modified diode and a threshold voltage Vref could be used for comparing to the input voltage V1 to determine whether the circuit is in a normal operation mode or a surge event mode.

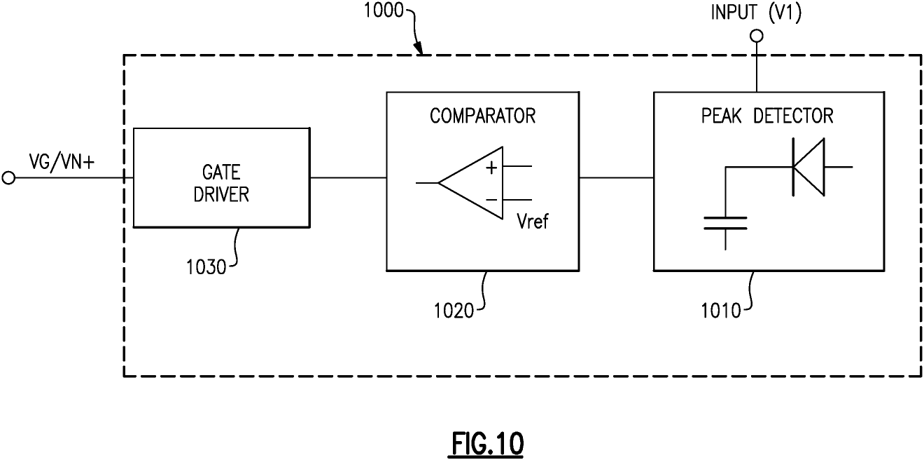

Moreover, the example diode control circuits of FIG. 7 and FIG. 9 illustrate passive control of the modified diode using configurations of transistors; however, it will be appreciated that active control may also be used. FIG. 10 illustrates an active diode control circuit 1000 for a current shunting circuit protection arrangement according to aspects of the present disclosure.. The active diode control circuit 1000 comprises a peak detector 1010, a comparator 1020, and a gate driver 1030. The peak detector 1010 may be configured to sense the input voltage at the anode of the modified diode, in particular, the peak detector 1010 may be configured to sense the maximum voltage from the input V1, which may correspond to an input from the low voltage IO pad 320, and to communicate this to the input of the comparator 1020.

The comparator 1020 may be configured to receive the input from the peak detector 1010 as well as a preset reference input Vref and to compare V1 and Vref. The preset reference input Vref may be configured to control the threshold transition between the normal operating mode and the surge event mode, e.g., Vref may be set at or around the expected VDD of the circuit block 310 to be protected. In this manner, during input surging conditions the comparator 1020 may determine that the value of V1 is larger than that of Vref and the comparator may then be configured to control the gate driver 1030 to pull the output of the gate driver down to a ground level. When the value of V1 is determined to be smaller than that of Vref by the comparator, i.e., during normal operations, the comparator may be configured to control the gate driver to output a certain voltage level.

For the example modified diode 600, this output of the gate driver 1030 may be connected to the gate electrode 650. Alternatively, for the example modified diode 800, this output of the gate driver 1030 may be connected to the N+ region 850. Where the gate driver 1030 outputs a ground level voltage, the active diode control circuit 1000 controls the modified diode to be in the surge event mode in which the modified diode acts like a single unmodified diode. Where the gate driver 1030 outputs the threshold voltage, the active diode control circuit 1000 controls the modified diode to be in the normal operation mode in which the modified diode provides an increased resistance.

In some embodiments, the gate driver 1030 may be controlled to output a variable voltage, for example to vary the amount of induced fixed space charges and therefore to provide some continuously variable control of the turn-on voltage of the modified diode controlled by the active diode control circuit 1000.

In an embodiment, the active diode control circuit 1000 may be configured to pull the voltage output by the gate driver 1030 down to ground in the event that one or more of the components of the active diode control circuit 1000 becomes unpowered, which may be as a result of an ESD event.

While the above disclosure has discussed configurations of SOI devices, it will be appreciated that equivalent structures, such as germanium-on-insulator devices may also be implemented in accordance with the present disclosure. Furthermore, the example diodes illustrated in the FIGs have used a typical N+/P-Well constructions; however, it will be appreciated that a P+/N-Well constructions may also be used provided that the voltage polarities were also reversed.

In the current shunting circuit protection arrangements of FIG. 5, FIG. 7, and FIG. 9, the circuit is configured to shunt current to ground in the surge event mode. Alternative configurations may instead direct the excess current away in a different manner, for example by shorting the positive and negative terminals of the voltage source.

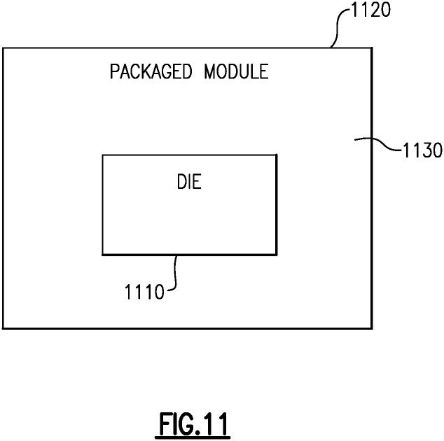

FIG. 11 is a die 1110 implemented in a packaged module 1120. Such a packaged module can include a packaging substrate 1130 configured to receive a plurality of components. In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

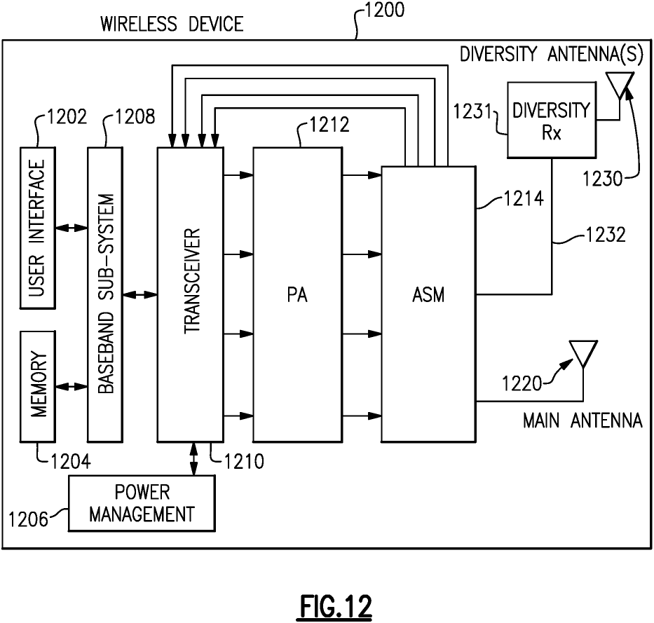

FIG. 12 depicts an example wireless device 1200 having one or more advantageous features described herein. In some embodiments, a module 1120 that includes one or more power amplifiers can also include one or more current shunting circuit protection as described herein.

In the example of FIG. 12, power amplifiers (PAs) are depicted in a PA module 1212; however, it will be understood that such power amplifiers can be implemented in one or more functional blocks, one or more devices such as die or modules, etc. Such power amplifiers can receive their respective RF signals from a transceiver 1210 that can be configured and operated to generate RF signals to be amplified and transmitted, and to process received signals. The transceiver 1210 is shown to interact with a baseband sub-system 1208 that is configured to provide conversion between data and/or voice signals suitable for a user and RF signals suitable for the transceiver 1210. The transceiver 1210 is also shown to be connected to a power management component 1206 that is configured to manage power for the operation of the wireless device 1200. Such power management can also control operations of the baseband sub-system 1208 and other components of the wireless device 1200.

The baseband sub-system 1208 is shown to be connected to a user interface 1202 to facilitate various input and output of voice and/or data provided to and received from the user. The baseband sub-system 1208 can also be connected to a memory 1204 that is configured to store data and/or instructions to facilitate the operation of the wireless device, and/or to provide storage of information for the user.

In the example of FIG. 12, a diversity receive (DRx) module 1231 can be implemented between one or more diversity antennas (e.g.,, diversity antenna 1230) and the front-end module. Such a configuration can allow an RF signal received through the diversity antenna 1230 to be processed (in some embodiments, including amplification by an LNA) with little or no loss of and/or little or no addition of noise to the RF signal from the diversity antenna 1230. Such processed signal from the DRx module 1240 can then be routed to the front-end module through one or more signal paths. In some embodiments, the wireless device 1200 may or may not include the foregoing DRx functionality.

In the example of FIG. 12, a plurality of antennas can be configured to, for example, facilitate transmission of RF signals from the PA module 1212. In some embodiments, receive operations can also be achieved through some or all of the antennas.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. A semiconductor device for shunting current in a circuit protection configuration, the device comprising:
a first semiconductor region having an anode electrical contact;
a second semiconductor region having a cathode electrical contact;
a third semiconductor region extending between the first semiconductor region and the second semiconductor region, the second semiconductor region and the third semiconductor region forming a PN junction therebetween; and
a gate coupled to the third semiconductor region, the gate controllable between a first mode in which additional space charges are induced in the semiconductor region to deplete the semiconductor region, and a second mode in which additional space charges are not induced in the semiconductor region.

2. The semiconductor device of claim 1 wherein the gate is a gate electrode adjacent to the third semiconductor region and the gate electrode is configured in the first mode to generate an electric field to exert a potential change in the third semiconductor region.

3. The semiconductor device of claim 2 wherein the gate electrode forms a p-varactor with the adjacent third semiconductor region.

4. The semiconductor device of claim 2 wherein the gate electrode is formed from a heavily doped polysilicon layer adjacent to an oxide insulator layer.

5. The semiconductor device of claim 1 wherein the gate is a fourth semiconductor region embedded in the third semiconductor region and configured to form a PN junction between the third and fourth semiconductor regions, the fourth semiconductor region configured to induce additional space charges in the third semiconductor region when a bias voltage is applied to the fourth semiconductor region.

6. The semiconductor device of claim 5 wherein a depth of the third semiconductor region is larger than a depth of the fourth semiconductor region.

7. The semiconductor device of claim 5 wherein the fourth semiconductor region is a heavily doped N+ region and the third semiconductor region is a p-type semiconductor region.

8. The semiconductor device of claim 1 wherein the first semiconductor region is a P+ region, the second semiconductor region is an N+ region, and the third semiconductor region is a p-type semiconductor region.

9. The semiconductor device of claim 8 further comprising a central P+ semiconductor region that divides the third semiconductor region into two semiconductor regions.

10. The semiconductor device of claim 1 wherein the semiconductor device is fabricated as a silicon-on-insulator device.

11. The semiconductor device of claim 1 wherein the PN junction is configured to be forward biased.

12. The semiconductor device of claim 1 wherein the second mode is a surge event mode during which the voltage received at the anode electrical contact is greater than a threshold voltage, and the first mode is a normal operation mode during which the voltage received at the anode electrical contact is less than the threshold voltage.

13. A circuit for shunting current in a circuit protection configuration, the circuit comprising:
a semiconductor device according to claim 1, the anode electrical contact for coupling to a first voltage source and the cathode electrical contact for coupling to ground; and
a coupling circuit configured to couple a second voltage level to the gate when a voltage of the first voltage source is below a threshold voltage, and configured to pull the gate down to a ground voltage when the voltage of the first voltage source is above the threshold voltage.

14. The circuit of claim 13 wherein the coupling circuit includes:
an n-channel field-effect transistor (FET) having a gate and a selectively conductive channel;
a first p-channel FET having a gate coupled to the anode electrical contact of the semiconductor device and having a selectively conductive channel configured to selectively couple the second voltage level to the gate of the semiconductor device; and
a second p-channel FET having a gate configured to couple to the second voltage level and having a selectively conductive channel configured to selectively couple the anode electrical contact to the gate of the n-channel FET, the selectively conductive channel of the n-channel FET being configured to selectively couple the gate of the semiconductor device to a ground node.

15. The circuit of claim 14 further comprising a resistor placed in the path between the gate of the semiconductor device and the selectively conductive channel of the n-channel FET.

16. The circuit of claim 13 wherein the cathode electrical contact of the semiconductor device is coupled to a ground node.

17. The circuit of claim 13 wherein the anode electrical contact of the semiconductor device is coupled to the first voltage source in parallel with a circuit block to be protected, the circuit configured to shunt excess voltage from the first voltage source.

18. The circuit of claim 13 wherein the coupling circuit includes:
a voltage peak detector coupled to the first voltage source and configured to sense a maximum voltage of the first voltage source;
a comparator coupled to the voltage peak detector and the threshold voltage, the comparator configured to output an indication of whether the maximum voltage of the first voltage source is greater than the threshold voltage; and
a gate driver configured to receive the indication from the comparator and configured to control the voltage coupled to the gate based on the indication.

19. The circuit of claim 18 wherein the second voltage level coupled to the gate by the gate driver when the first voltage source is below a threshold voltage is a variable voltage level.

20. The circuit of claim 18 wherein the gate driver is configured to pull the gate down to a ground voltage in the event that a portion of the coupling circuit becomes unpowered.
